(19) United States
(12) Patent Application Publication
(10) Pub. No.: US 2013/0170481 A1
(43) Pub. Date: Jul. 4, 2013

(54) LOAD MONITORING SYSTEMS, NODES, AND RELATED METHODS

(71) Applicants: John R. Crawford, Raleigh, NC (US); Henry D. Carr, Bowie, MD (US); Chet W. Helms, Raleigh, NC (US); Kevin F. Cook, Raleigh, NC (US); Andy J. Borleske, Garner, NC (US)

(72) Inventors: John R. Crawford, Raleigh, NC (US); Henry D. Carr, Bowie, MD (US); Chet W. Helms, Raleigh, NC (US); Kevin F. Cook, Raleigh, NC (US); Andy J. Borleske, Garner, NC (US)

(21) Appl. No.: 13/730,968

(22) Filed: Dec. 29, 2012

Related U.S. Application Data
(60) Provisional application No. 61/581,176, filed on Dec. 29, 2011.

(51) Int. Cl. G01R 21/00

(52) U.S. Cl. CPC G01R 21/00
USPC 370/338; 370/401

(57) ABSTRACT

Load monitoring systems, nodes, and related methods are disclosed. According to an aspect, a load monitoring system includes multiple load monitoring nodes. Each node is in communication with a power measurement input and is configured to capture load data at the respective power measurement input. The system includes a network communications device configured to receive the captured load data from each of the load monitoring nodes and to communicate the captured load data to a remote computing device.

### CROSS REFERENCE TO RELATED APPLICATIONS

This application claims the benefit of U.S. Provisional Patent Application No. 61/581,176, filed Dec. 29, 2011, the content of which is hereby incorporated herein by reference in its entirety. Further, this application is related to co-pending U.S. Utility patent application Ser. No. ______, filed simultaneously herewith and titled “LOAD MONITORING NODES AND APPARATUSES,” the content of which is hereby incorporated herein by reference in its entirety.

### TECHNICAL FIELD

The present disclosure relates to load monitoring. Particularly, the present disclosure relates to load monitoring systems, nodes, and related methods.

### BACKGROUND

The movement for energy conservation and smart grid technology has recently seen tremendous momentum. The demand for power increases yearly, increasing the need for better power conservation products. Power companies are working on variable pricing for power, increasing the price during peak load times, and lowering it during off-peak hours. In addition, energy-efficient appliances have entered the marketplace for helping to manage the rising cost of power and the increased desire of consumers to have “green” products.

In view of the interest in providing techniques and products for conserving energy, it is desired to provide improved energy-conservation electrical and control systems.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Disclosed herein are systems and methods for energy conservation and management. The disclosed subject matter includes a power efficient system for monitoring and managing power in homes and commercial facilities. The system may include a load monitoring device configured to fit into a power receptacle box and to monitor and control power usage thereat. Further, the load monitoring device may report its power usage along with other load monitoring devices at the home or commercial facility to a remote server or other computing device.

According to an aspect, a load monitoring system includes multiple load monitoring nodes. Each node is in communication with a power measurement input and is configured to capture load data at the respective power measurement input. The system includes a network communications device configured to receive the captured load data from each of the load monitoring nodes and to communicate the captured load data to a remote computing device.

According to another aspect, a method of load monitoring includes capturing load data at a power measurement input. The load data may be captured by each of multiple load monitoring nodes that are each in communication with the power measurement input. The method may also include receiving, at a network communications device, the captured load data from each of the load monitoring nodes. Further, the method may include communicating, at the network communications device, the captured load data to a remote computing device.

### BRIEF DESCRIPTION OF THE DRAWINGS

The foregoing summary, as well as the following detailed description of various embodiments, is better understood when read in conjunction with the appended drawings. For the purposes of illustration, there is shown in the drawings exemplary embodiments; however, the presently disclosed subject matter is not limited to the specific methods and instrumentalities disclosed. In the drawings:

FIG. 1A is a block diagram of an example load monitoring system for monitoring and managing power usage at multiple power measurement inputs in accordance with embodiments of the present disclosure;

FIG. 1B is a block diagram of another example load monitoring system for monitoring and managing power usage at multiple power measurement inputs in accordance with embodiments of the present disclosure;

FIG. 2 is a block diagram of an example load monitoring node connected to a power measurement input in accordance with embodiments of the present disclosure;

FIG. 3 is a block diagram of an example network communications device in accordance with embodiments of the present disclosure;

FIG. 4A is a block diagram of an example server in accordance with embodiments of the present disclosure;

FIG. 4B is a block diagram of another example server in communication with a network communications device and a client computing device in accordance with embodiments of the present disclosure;

FIG. 5 is a flowchart of an example method for capturing and analyzing load data in accordance with embodiments of the present disclosure;

FIG. 6 is a schematic diagram of an example sensor circuit for detecting load data in accordance with embodiments of the present disclosure;

FIG. 7 is a schematic diagram of an example system level block diagram of a load monitoring system in accordance with embodiments of the present disclosure;

FIG. 8 is a flow chart of high-level pseudo code of the ZigBee mesh network shown in FIG. 7 in accordance with embodiments of the present disclosure;

FIG. 9 is a flow chart of high-level pseudo code of a microcontroller of an outlet or node 704 shown in FIG. 7 in accordance with embodiments of the present disclosure;

FIGS. 10A and 10B are flow charts of high-level pseudo code of the controller shown in FIG. 7 in accordance with embodiments of the present disclosure;

FIGS. 11A and 11B depict a flow chart of high-level pseudo code of the web server as shown in FIG. 7 for communicating with a controller in accordance with embodiments of the present disclosure;

FIG. 12 is a flow chart of high-level pseudo code of the web server as shown in FIG. 7 in accordance with embodiments of the present disclosure;

FIG. 13 is a circuit diagram of a power supply in accordance with embodiments of the present disclosure;

FIG. 14 is a circuit diagram of a power measurement module in accordance with embodiments of the present disclosure;

FIG. 15 depicts a webpage of an example user interface dashboard showing a day view in accordance with embodiments of the present disclosure;

FIG. 16 depicts a webpage of an example user interface dashboard showing a minute view in accordance with embodiments of the present disclosure;

FIG. 17 depicts a webpage of an example user interface dashboard showing a system overview in accordance with embodiments of the present disclosure;

FIG. 18 depicts a webpage of an example user interface dashboard showing outlet overview states in accordance with embodiments of the present disclosure;

FIGS. 19A and 19B depict webpages of an example outlet overview in accordance with embodiments of the present disclosure;

FIGS. 20A and 20B are top perspective views of a load monitoring node attached to an electrical outlet box in accordance with embodiments of the present disclosure; and

FIG. 21 is a top perspective view of a load monitoring node attached to an electrical plug receptacle in accordance with embodiments of the present disclosure.

### DETAILED DESCRIPTION

The presently disclosed subject matter is described with specificity to meet statutory requirements. However, the description itself is not intended to limit the scope of this patent. Rather, the inventors have contemplated that the claimed subject matter might also be embodied in other ways, to include different steps or elements similar to the ones described in this document, in conjunction with other present or future technologies. Moreover, although the term “step” may be used herein to connote different aspects of methods employed, the term should not be interpreted as implying any particular order among or between various steps herein disclosed unless and except when the order of individual steps is explicitly described.

As used herein, the term “load data” can be any representation of power use at a particular point in an electrical system. For example, load data may represent power use at a power outlet within a residence or commercial facility. Load data may include a representation of, for example, but not limited to, volts, amperes, watts, hertz, volt-amps, kilowatt hours, power factor, and the like.

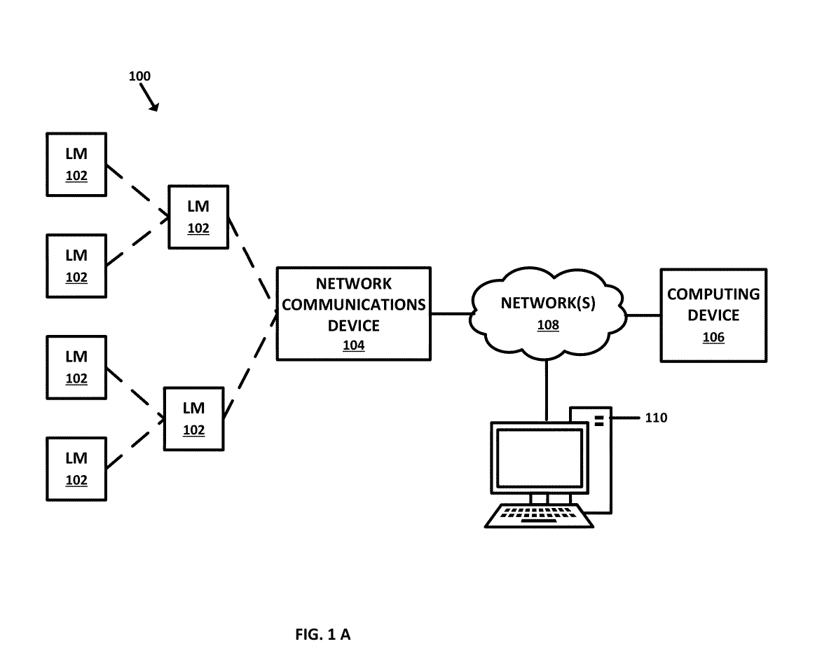

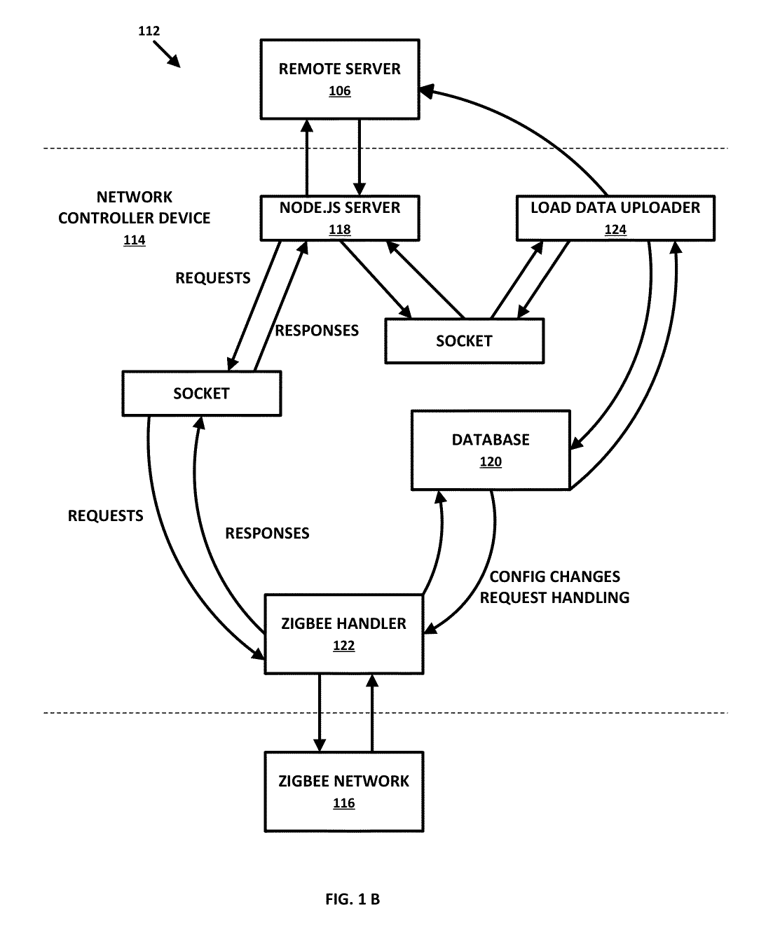

FIG. 1A illustrates a block diagram of an example load monitoring system 100 for monitoring and managing power usage at multiple power measurement inputs in accordance with embodiments of the present disclosure. Referring to FIG. 1A, the system 100 includes multiple load monitoring nodes 102 that are each positioned near a respective power measurement input (not shown). Each load monitoring node 102 may be configured to capture load data at its respective power measurement input. For example, load data may be information about power usage, such as instantaneous current load, at a power measurement input. Each load monitoring node 102 may periodically communicate or otherwise suitable communicate load data to a network communications device 104. The time interval at which data is communicated may be adjustable.

In accordance with embodiments, one of more of the load monitoring nodes 102 may include a relay function configured to receive captured load data from another node 102. The recipient node 102 may store the data in its memory and subsequently communicate the load data that it received along with the received load data to the network communication device 104. In this way, such nodes may provide a relay service to one or more other load monitoring nodes.

In accordance with embodiments, the load monitoring devices 102 may be configured for communication in a wireless local area network (WLAN). In an example, the load monitoring devices 102 and the network communications device 104 may be positioned within a residence or commercial facility. More particularly, the load monitoring devices 102 may be positioned in proximity to power measurement inputs or outlets within the environment. The nodes 102 may be configured to communicate within the WLAN for sending captured load data to the network communications device 104. In one example, the network may be ZigBee network (a wireless network based on IEEE 802.15.4), a BLUETOOTH® network, or any other suitable network. In an example, the nodes 102 and device 104 may be configured with suitable ZigBee interfaces or other suitable communications interfaces. Another example wireless network may be implemented in accordance with IEEE 802.11 (Wi-Fi).

The network communications device 104 may be configured to receive captured load data from each of the load monitoring nodes 102. The device 104 may also locally store the load data. Further, the network communications device 104 may subsequently communicate the captured load data to a remote computing device or server 106 via one or more networks 108. The data may be communicated to the server 106 and/or one or more other computing devices at predetermined intervals. The device 104 may, for example, include a suitable network port for interfacing with a local area network (LAN) or through any other suitable network component for communicating with the network(s) 108. The network(s) 108 may include, but is not limited to, the Internet, a mobile wireless network, the like, or combinations thereof. A firewall may be suitably configured between the network communications device 104 and the network(s) 108. The network communications device 104 may be a ZigBee hub, a gateway, or other suitable network components for storing data received from the load monitoring nodes 102 and for communicating the data to the server 106. As an example, the network communications device 104 may be configured with gateway functions for managing communications between a WLAN including the nodes 102 and the Internet.

The remote server 106 may be configured to receive the captured load data from the network communications device 104, store the data, and process the data to generate analysis information. For example, the server 106 may display or otherwise present the data to a user, and provide the user with analysis results. The analysis can include, but is not limited to, providing users with energy usage recommendations. For example, users can be provided with recommendations for balancing their load during times that are cost sensitive, for example, if they are running on time-of-use billing from a utility service.

In accordance with embodiments, the computing device 106 may communicate with a client computing device 110 to provide its generated analysis information. As an example, the client computing device 110 may be provided with information for comparing their current usage against their historical usage for aiding the user in realizing cost savings. In this way, the user can be provided with a tool for lowering their power usage by giving him or her access to load data and analysis information.

The server 106 may include an analytics engine for sorting through load information stored in a database. The analytics engine may determine interesting data points or trends with load information. In response to determining the interesting data points or trends, the server 106 may provide the information to the device 110 for presentation to a user. In the alternative for example, the information may be provided to a user via email or any other suitable communications technique.

In an example of presenting data and analysis information to a user, the user may use the computing device 110 to register with the server 106. The server 106 or another computing device, such as a web server, may provide a web page to the computing device 110 for displaying or otherwise presenting the data and analysis information to the user.

In accordance with embodiments, one or more of the load monitoring nodes 102 may be configured to control power output at its respective power measurement input. For example, a node 102 may switch the terminal between an on and off state for providing power at the terminal. Further, nodes 102 may receive instructions for controlling the power output at its respective terminal. For example, the client computing device 110 may receive control information from its user and communicate control instructions based on the control information.

In accordance with embodiments, one or more of the load monitoring nodes 102 may be configured to be powered by its respective power measurement input and/or a battery. For example, a node 102 may be hard wired to its respective terminal for receiving power therefrom. In another example, a node 102 may include a battery for providing power to the hardware of the node 102. In yet another example, a node 102 may be hard wired to its respective terminal and include a battery. In this example, the node 102 may operate in one of two power modes that are user selectable. In one power mode, the node 102 may receive power from the battery. In another power mode, the node 102 may receive power from its respective power measurement input.

FIG. 1B is a block diagram of another example load monitoring system 112 for monitoring and managing power usage at multiple power measurement inputs in accordance with embodiments of the present disclosure. Referring to FIG. 1B, the system 112 includes a remote server 106, a network controller device 114, and a ZigBee network 116. The remote server 106 may have the functionality of the computing device 106 shown in FIG. 1A. The ZigBee network 116 may include multiple load monitoring devices.

The network controller device 114 may include a node.js server 118, a database 120, a ZigBee handler 122, and a load data uploader 124. In an example, the ZigBee handler 122 may be written in any suitable software language such as C++. In another example, the uploader 124 may be written in any suitable software language such as the PYTHON™ software language.

The node.js server 118 may handle requests from the remote server 106. In an example, a request may be for any kind of change or request for information from the network controller device 114 or any of the load monitoring nodes within the network 116. Responses to these changes or requests for information may be routed through node.js server 118.

Database 120 can store information needed to run the software applications, such as the node.js server 118 and the uploader 124. Other example uses for the database 120 may be for storing application configurations, network controller information, and load profile data from the load monitoring nodes of the network 116.

The ZigBee handler 122 may handle requests and responses from the load monitoring nodes within the network 116. The ZigBee handler 122 may control timing for when the load monitoring nodes upload their load data and stores the received data in the database 120. Further, the ZigBee handler 122 may manage formation of the network 116 as the coordinator. The ZigBee handler 122 may also manage other network related operations such as, but not limited to, routing, configuration, formation, and the like.

The load data uploader 124 may periodically send new load data information to the remote server 106 via an HTTPS POST request message. The load data uploader 124 may keep track of information has been uploaded to the server by use of an index stored in the database 120 for each load data entry in a load data table in the database.

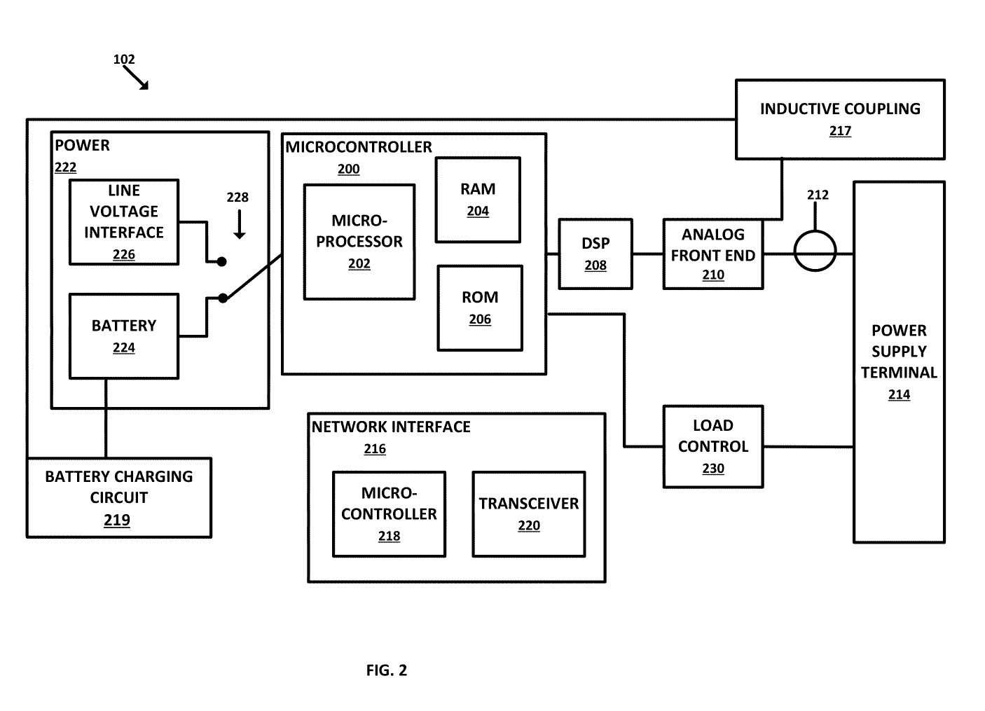

FIG. 2 illustrates a block diagram of an example load monitoring node connected to a power measurement input in accordance with embodiments of the present disclosure. Referring to FIG. 2, the node 102 includes a microcontroller 200 comprising a microprocessor 202, random access memory (RAM) 204, and read only memory (ROM) 206. Alternatively, the microcontroller 200 may include any suitable hardware, software, firmware, the like, or combinations thereof for implementing the functions described herein. For example, the microcontroller 200 may be in communication with a suitable interface including a digital signal processor (DSP) 208, an analog front end module 210, a voltage adaptor circuitry 212 and the inductive coupling circuitry 216 for capture of load data from a power measurement input 214. The voltage adaptor circuitry 212 can be electrically connected to the voltage sources of the load of the power measurement input 214. The inductive coupling circuitry 216 can be inductively coupled to the power measurement input. An example inductive coupling would be a current transformer or a Rogowski coil. In addition to providing current measurement, the inductive coupling may be used to source power to charge the battery using the battery charging circuit 219. Voltage and current signals can be sent through the analog front end 210. Subsequently, the signals are sent to the DSP 208 to be processed for creating useful measurements, which may include load data for use in analyzing an electrical load of the power measurement input 214. The microprocessor 202 may process and locally store the load data. A load may be determined based on a direct line connection for measuring voltage and an inductive current measurement. In an example, a node may be operable in a battery-powered mode during which the battery is charged via an inductive coupling to a power line.

The node 102 includes a network interface 216 in communication with the microcontroller 200. The network interface 216 may be configured to communicate within a wireless network, such as a network including other load monitoring nodes as shown in FIG. 1A. In this example, the network interface 216 is configured as a ZigBee wireless networking interface that can be controlled by the microcontroller 200 to send captured load data upstream to a network communications device (e.g., the network communications device 104 shown in FIG. 1A) or to another load monitoring node for relay to the network communications device. The microcontroller 200 can control the network interface 216 to send captured load data at predetermined time intervals. In an example, the network of nodes can implement a mesh network function for collectively handling network traffic from other load monitoring nodes and the network traffic among one another without the microcontroller 200 being needed to handle requests. The network interface 216 may include a microprocessor 218, a transceiver 220, or any other suitable component for implementing its functionality.

Components of node 102 may be powered by a power module 222. In an example, the power module 222 may include a battery 224 and a line voltage interface 226 for providing power to components of the node 102. The microcontroller 200 may control the power module 222 to operate in one of two power modes. In one power mode, power may be received from the battery 224. In another power mode, power may be received from the respective power measurement input 214 via the line voltage interface 226. In the battery-supplied mode, the microcontroller 200 may control circuitry to interface with the battery 224 for receipt of power therefrom. In the power measurement input-supplied mode, the microcontroller 200 may control circuitry to interface with the line voltage interface, which is electrically connected to a voltage line of the power measurement input 214 for receipt of power therefrom. It is noted that the load data may be captured or measured from the voltage line. In an example, the modes may be user selectable. In this example, the node 102 may include a mechanical switch 228 for switching between the different modes.

In a battery-supplied mode in accordance with embodiments, the node 102 may determine a power consumed at the power measurement input 214 by use of the equation P=V*I, where P is power, V is voltage source, and I is a current source. The voltage value may be coded into the node 102 by installation personnel. The node 102 may include an inductive coupling circuit 217 that is placed over the line of the power measurement input 214 to obtain current measurements. In a battery-supplied mode, the device's 102 only needed input may be the inductive coupling for obtaining current measurements. An example of the inductive coupling is a current transformer.

In another example of measuring load data, a Rogowski coil may be positioned over a wire to obtain measurements. As an example, the equation P=V*I may be used to obtain additional information based on the measurements. The Rogowski coil may be used, for example, during battery operation.

In a power supply terminal-supplied mode, the device 102 may be powered by the same voltage source as the voltage measurement source. The device 102 may be powered by use of an AC/DC converter rated within a voltage range of the voltage measurement source.

The node may also include a load control module 230 for controlling power output by the power measurement input 214. In an example, the load control module 230 is a solid state relay switch, although the module may be any suitable switch.

In accordance with embodiments, a load monitoring node may obtain power data from a device being measured. The node may report the data to a network controller device using a suitable wireless network. Two primary components to the nodes are load monitoring and network components. Features of the load monitoring load include, but are not limited to, updating firmware over the network, gathering power data at multiple interval rates (e.g., 15 minutes per interval or 1 minute per interval), acting as a router for other nodes on the network, and reporting power data to the network controller device.

The load monitoring component can measure the power values (e.g., kWh, VAR, I, V, power factor, and the like) and stores them in intervals. The set of intervals can make up an interval bank. Each load monitoring node contains more than one interval bank, allowing different interval lengths, measured in time, for each interval bank. Interval lengths can be unique for each load monitoring device on the network and multiple interval lengths can occur at the same time.

The network component can connect the load monitoring node to the rest of the network. The nodes may build a mesh network, connecting all nodes to the network controller device. Periodically, based on a user configuration, interval data can be sent on the network to the network controller device. Other network traffic can fall under the categories of configuration information, upgrade images, other non-routine requests for interval data, and the like.

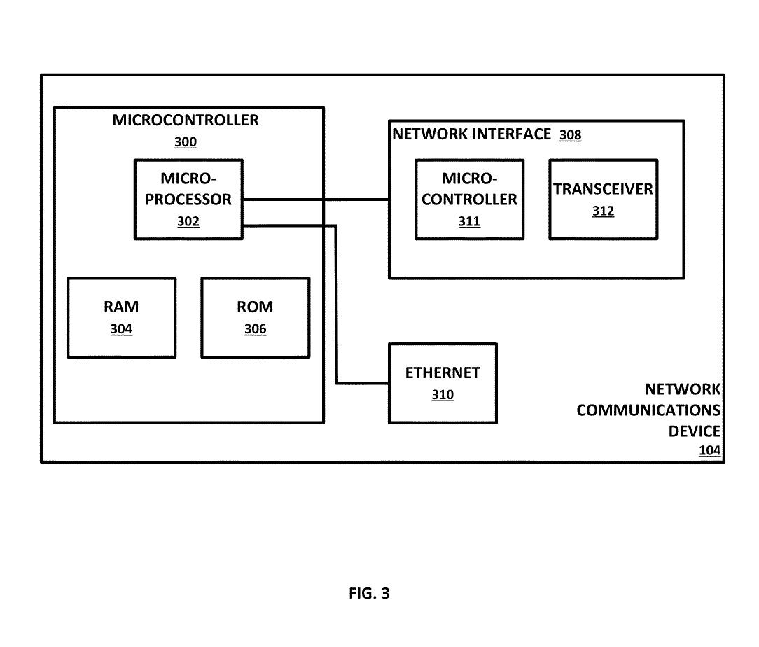

FIG. 3 illustrates a block diagram of an example network communications device 104 in accordance with embodiments of the present disclosure. Referring to FIG. 3, the device 104 includes a microcontroller 300 comprising a microprocessor 302, RAM 304, ROM 306, a network interface 308, and an Ethernet module 310. Alternatively, the microcontroller 300 may include any suitable hardware, software, firmware, the like, or combinations thereof for implementing the functions described herein. For example, the device 104 may be configured to receive load data from load monitoring nodes (e.g., nodes 102 shown in FIG. 1A) and to communicate the load data to a remote computing device (e.g., computing device 106 shown in FIG. 1A).

The device 104 may include a network interface 308 configured to communicate with load monitoring nodes, such as nodes 102 shown in FIG. 1A. In an example, the network interface 308 may be configured as a ZigBee interface for communicating with nodes within a ZigBee network. Alternatively, the network interface 308 may be configured to communicate with nodes within a BLUETOOTH® network or any other suitable network. The microcontroller 300 may control the network interface 308 for receiving load data from nodes and for sending instructions to nodes. The network interface 308 may include a microcontroller 311 and transceiver 312.

The Ethernet module 310 may be controlled by the microcontroller 300 and configured to communicate with a network, such as network(s) 108 shown in FIG. 1A. In an example, the Ethernet module 310 may be connected to a firewall. Further, the Ethernet module 310 may be controlled to communicate load data to a remote computing device, such as computing device 106, via the network. The Ethernet module 310 may also receive communications, such as instructions for nodes, from the remote computing device via the network.

In accordance with embodiments, the network communications device 104 may operate alone or together with one or more other network communications devices for serving as a network hub for communicating with nodes and the Internet. The device 104, serving as a network hub, may act as a main controller of a ZigBee network of nodes in the initial set up of the network and sending information and commands to the nodes. Nodes may periodically send their load data to the device 104 for storage in memory and for subsequent communication to a remote server. In an example, the device 104 may gather data, store the data, and communicate it to the remote server at predetermined intervals. The network interface 308 may serve as a ZigBee interface accessible by the microcontroller 300. The ZigBee interface may be configured as a coordinator of the network of nodes for controlling the network. The microcontroller 300 may determine when to use the ZigBee interface for communicating with the network of nodes to send or receive communications.

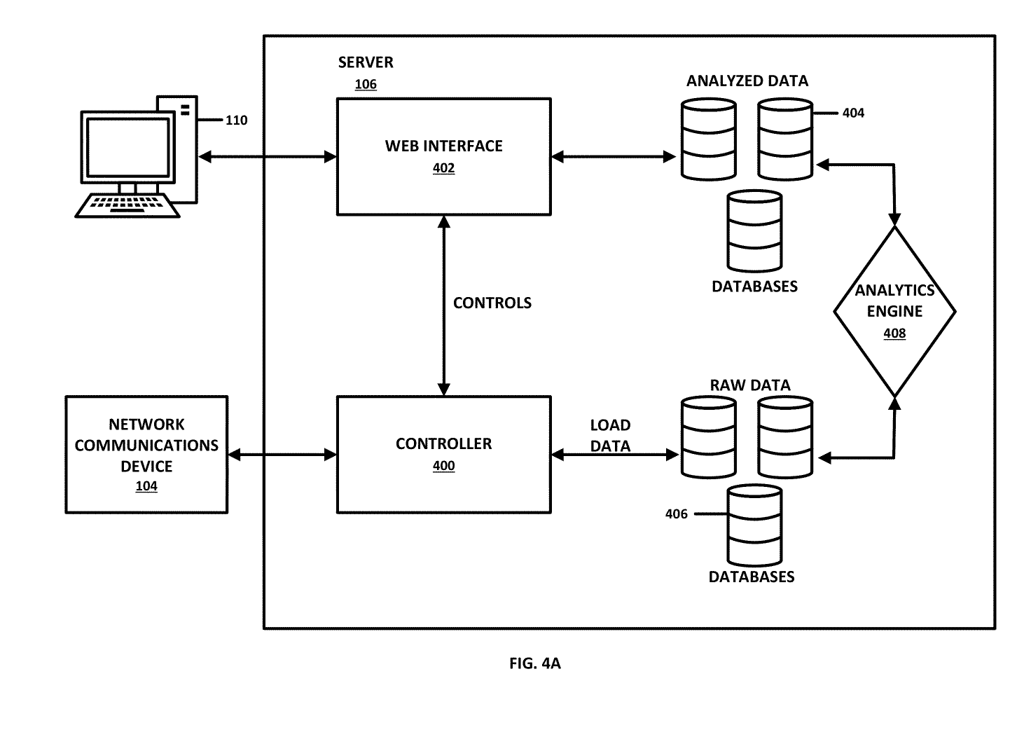

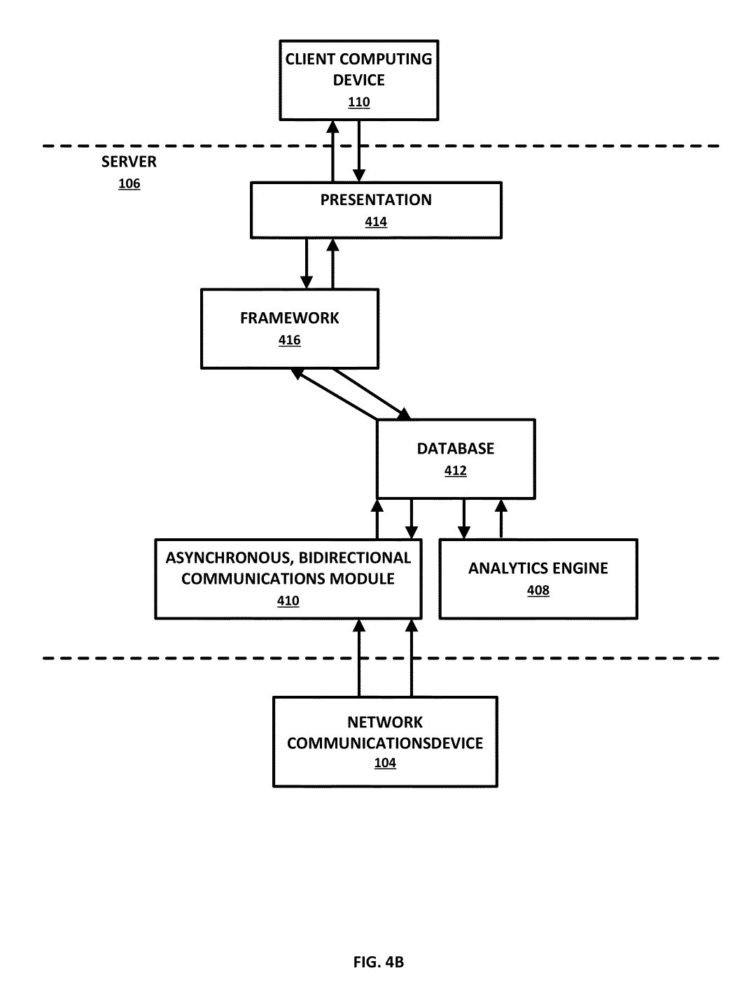

FIG. 4A illustrates a block diagram of an example server 106 in accordance with embodiments of the present disclosure. Referring to FIG. 4A, the server 106 includes a controller 400, a web interface module 402, databases 404 and 406, and an analytics engine 408. The controller 400 may include any suitable hardware, software, firmware, the like, or combinations thereof for implementing the functions described herein. For example, the server 106 may be configured to communicate with the network communication device 104 for receipt of load data captured by nodes and for communicating instructions thereto. The server 106 may process captured load data for generating analysis information. The server 106 may be configured to communicate with the client computing device 110 for sending the analysis information thereto for presentation to a user. The web interface module 402 may be configured to serve webpages to client computing devices for presenting captured load data and analysis information.

The controller 400 is configured to communicate with one or more different network communications devices operating within different environments (e.g., residential or commercial facilities). In an example, the controller 400 may comprise one or more servers configured to communicate with multiple network communications devices managing multiple nodes at any time.

FIG. 4B is a block diagram of another example server 106 in communication with a network communications device 104 and a client computing device 110 in accordance with embodiments of the present disclosure. Referring to FIG. 4B, the server 106 may include four primary components: an asynchronous, bidirectional communication module 410; a database 412; an analytics system 408; and a presentation module 414. The presentation module 414 may function as a web interface or web server for presenting data to the client computing device 110. The presentation module may include a framework 416, an authentication system (not shown), and a user presentation system (not shown).

The asynchronous, bidirectional communications module 410 may handle communication to or from the network hub system or network communications device 104 as described in examples provided herein. The module 410 can handle multiple connections from multiple systems at one time. Data communicated to the network communications device 104 may include, but is not limited to, new device configurations/system updates, or power control information (i.e., turning a device on or off remotely), and the like. Data received from the network communications device 104 may include, but is not limited to, power information from each device, acknowledgement of control information, and the like.

The database can hold any information that needs to be stored on the server. This can include, but is not limited to, power information received from each device, historical data from other locations, weather information, results of analytics performed on data collected, or usage patterns. Data in the database(s) can be retrieved by the webserver, the analytics backend, or node.js.

The analytics engine 408 can perform a number of different sets of analytics including analytics described in examples provided herein. In an example, the analytics engine 408 can detect usage patterns. Based on power pricing data and weather information (e.g., temperature), the analytics engine 408 can recommend an optimal time (e.g., day, week, etc.) for a facility to run that is expected to be the lowest cost for the facility. In another example, analytics can also be performed on a per device level. Based on device level analytics, this information can be used for making recommendations for the purchase of new equipment that is more power efficient than a currently-used device.

The presentation module can be used to present to the user various load data and analytics data. The framework 416 can provide an overall structure of a website presented to a user. Further, the framework 416 can allow data to be transferred from the database 412 to the presentation module 414, which may subsequently present the data to the user at the device 110, for example. In an example, the presentation module 414 may display a series of graphs and charts that may present detailed power information, or it may display information about the system/devices being monitored. The authentication system of the presentation module 414 may receive a unique username and password from a user for authenticating the user. After successful authentication, each user may be presented with his or her own, unique, customizable dashboard that displays information about his or her respective system. A user may also be given access to systems of other users at the discretion of the respective user of the system.

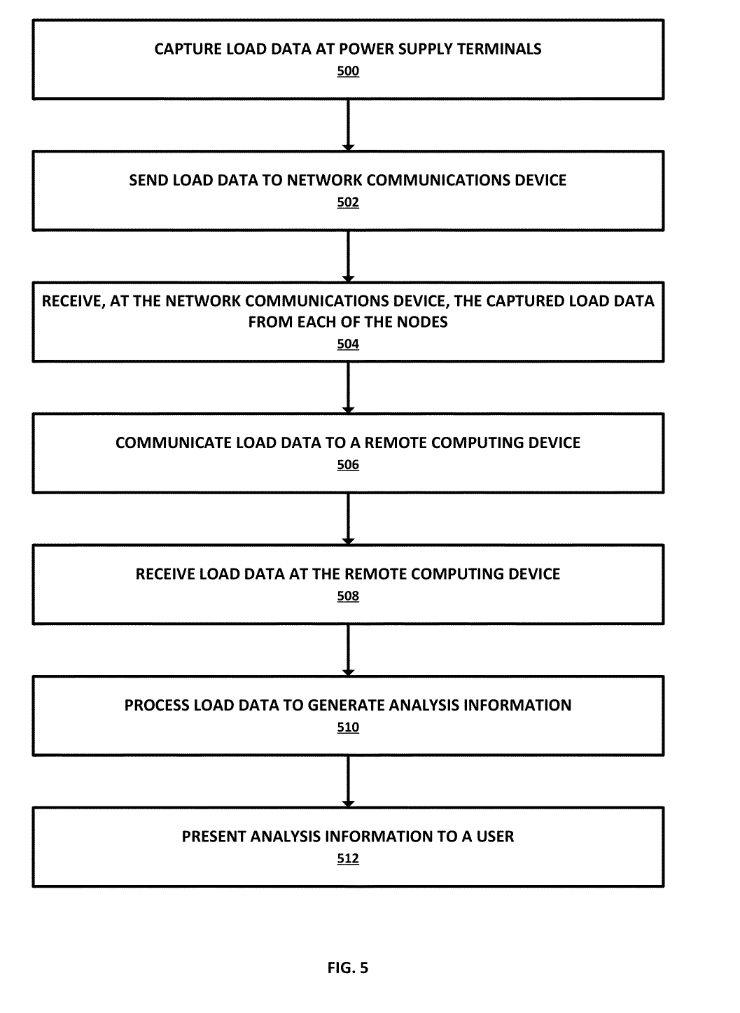

FIG. 5 illustrates a flowchart of an example method for capturing and analyzing load data in accordance with embodiments of the present disclosure. The example process may be implemented by the system 100 shown in FIG. 1A and reference is made thereto in describing this example process; however, it is noted that this process or any other process, technique, or function described herein may be implemented by any suitable system.

Referring to FIG. 5, the method includes capturing load data at power measurement inputs (step 500). For example, each of the nodes 102 of the system shown in FIG. 1A may capture load data at their respective power measurement inputs. The nodes 102 may subsequently send their load data to the network communications device 104 or another node 102 for relay to the device 104 (step 502).

The method of FIG. 5 includes receiving, at the network communications device, the captured load data from each of the nodes (step 504). For example, microcontroller 300 of the device 104 shown in FIG. 3 may control receipt of the data and store the data in memory. The device may subsequently communicate the load data to a remote computing device (step 506). For example, the load data may be communicated to the server 106 shown in FIG. 4.

The method of FIG. 5 includes receiving the load data at the remote computing device (step 508). For example, the server 106 shown in FIG. 4 may receive load data from the device 104. Controller 400 may control the receipt of the load data and its storage as raw data in databases 406.

The method of FIG. 5 includes processing the load data to generate analysis information (step 510). For example, the analytics engine 408 may access the raw load data stored in the databases 406 and process the load data to generate analysis information. The analyzed data may be stored in databases 404. The analytics engine 408 may operate in parallel with other aspect of the system. The analytics engine 408 can communicate with databases 406 and make decisions based on the data as well as data gathered outside of the server 106. The analytics engine 408 may store the analyzed data in databases 404 in a format suitable for read or viewing by a user.

The method of FIG. 5 includes presenting analysis information to a user (step 512). For example, a webpage may be generated including the analyzed data in a suitable format (e.g., a graph or text data) for view and interpretation by a user. The web interface module 402 may communicate the webpage to the client computing device 110 for display to the user. As an example, a user may view current load information as compared to their historical data usage. In another example, the user may view results that come from the analytics engine 408 that gives him or her recommendations or tips. In another example, the presented information may include statistical information or data.

In accordance with embodiments, load profile data may also be requested and obtained from load monitoring nodes. Such data may be obtained in a manner similar to the example method shown in FIG. 5.

In accordance with embodiments, a user interface at a client computing device may present various analysis information. The information may include presenting measured real power usage and instantaneous load. This information may be displayed as a graph over time, a graph over device/categorical usage, cost per unit time (e.g., hour, day, week, month, or year), and the like. In an example, visual historical data may be presented. The presentation may indicate which outlets are currently on or off. In another example, particular devices may be assigned to outlets, and the presentation may indicate information about each device. Further, a user may manually enter pricing tier information from a utility provider. In another example, utility usage data may be viewed from a smart meter or smart appliances. Usage data maybe compared to comparable houses or a user's historical usage.

In accordance with embodiments, a user interface at a client computing device may allow control at outlets or appliances. For example, the user may schedule outlets or appliances to turn on or off by scheduled time events. In another example, outlets, appliances, or devices may be scheduled to turn on or off when changing pricing tiers set by a utility provider. In another example, outlets or appliances may be scheduled to turn on or off for a load shed event set by a utility provider. Rules on what appliances and outlets may be set to cut for particular load shed events.

In accordance with embodiments, a load monitoring node may engage a two-plug 120 VAC junction box. In an example, the node may include a sensor circuit configured to output a voltage proportional to a current load on a line of the junction box. The sensor circuit may also output a voltage proportional to a voltage difference across the load. The output range may be between 0 VAC and 125 VAC.

In accordance with embodiments, the load monitoring node may engage a 3 phase power outlet. Further, for example, one phase of the 3 phases may be fed into the power supply of the load monitoring node.

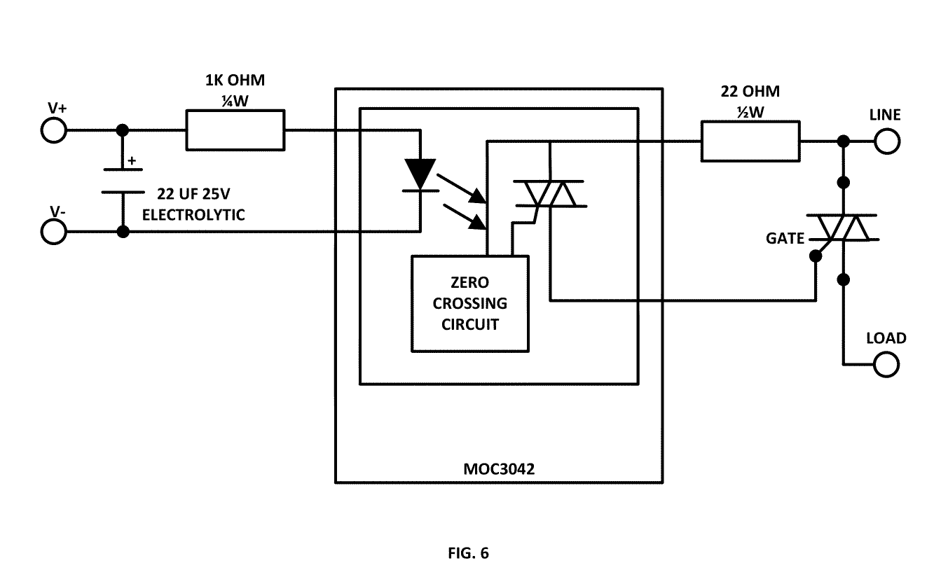

FIG. 6 illustrates a schematic diagram of an example relay switch 600 for detecting load data in accordance with embodiments of the present disclosure. Referring to FIG. 6, the relay switch 600 includes an optocoupler to isolate the microcontroller from the power and a relay suitable for voltages within the range of operation according to the power supply. As an example, the relay may be a solid state relay or a mechanical relay. A mechanical relay may be used in industrial applications having higher voltages.

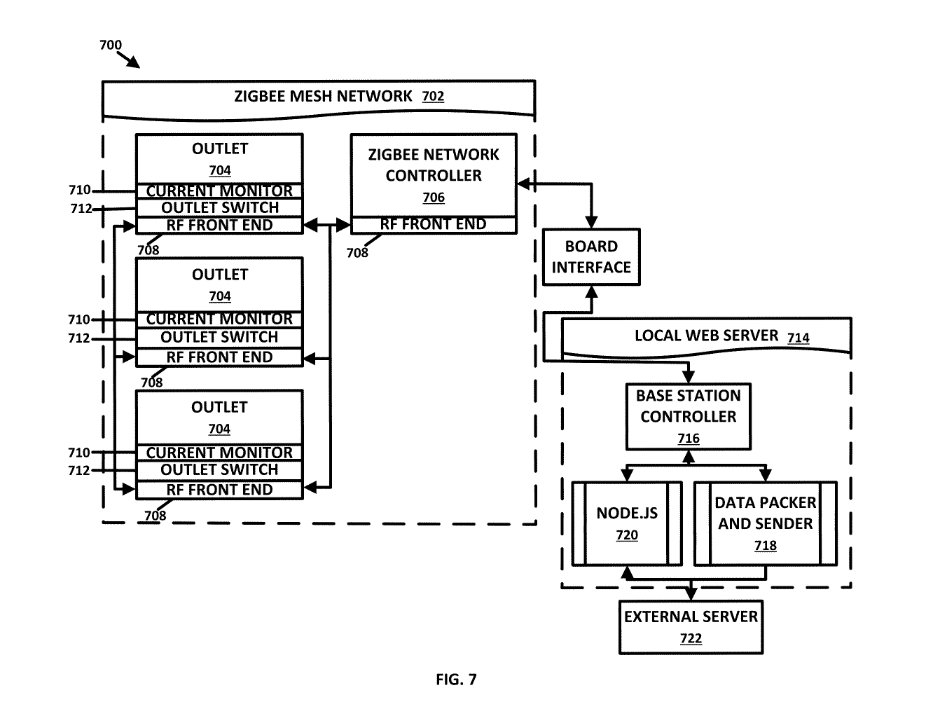

In accordance with embodiments of the present disclosure, FIG. 7 illustrates a schematic diagram of an example system level block diagram of a load monitoring system 700. In this example, a user may have a local web server for use in locally monitoring nodes. In this way, the user may locally store data gathered from nodes. The web server may also provide the function of pushing up data to a remote data server in accordance with examples disclosed herein. Referring to FIG. 7, the example system 700 includes a ZigBee mesh network 702 including multiple outlets or node 704. Each outlet 704 may include a load monitoring node in accordance with embodiments of the present disclosure. The system 700 may also include a ZigBee network controller 706 communicatively connected to each outlet 704 for receiving captured load data. The controller 706 may send load data to a remote server. In addition, the controller 706 may send and receive other information such as, but not limited to, configuration information, relay information, and commands. Nodes of the outlets 704 and the controller 706 may communicate by use of radio frequency (RF) front end components 708 or any suitable wireless network interface. Outlets 704 may each include a current monitor 710 for monitoring and capturing current usage. Further, outlets 704 may each include an outlet switch 712 for turning on and off power at the outlet.

The system 700 may include a local web server 714 configured to receive the captured data of current usage. The server 714 may analyze the current usage data and generate analysis information based upon the data. The server may include a base station controller 716 for controlling the operations of the controller 716. A data packager and sender module 718 may be configured to package and send current usage data and analysis information to client computing devices for presentation to users. Node.js 720 acts as a way to communicate commands or any other kind of data between the load monitoring network 700 and the remote server. Node.js 720 may be implemented as software for handling communications between the network 702 and a remote server. Node.js 720 may also implement functions for handling data such as, but not limited to, load information being sent to or from the remote server, commands being sent to or from the remote server, and the like. A board interface may manage communications between controller 706 and server 714. An extended server 722 may be in communication server 714 and provide additional computing resources to the server 714.

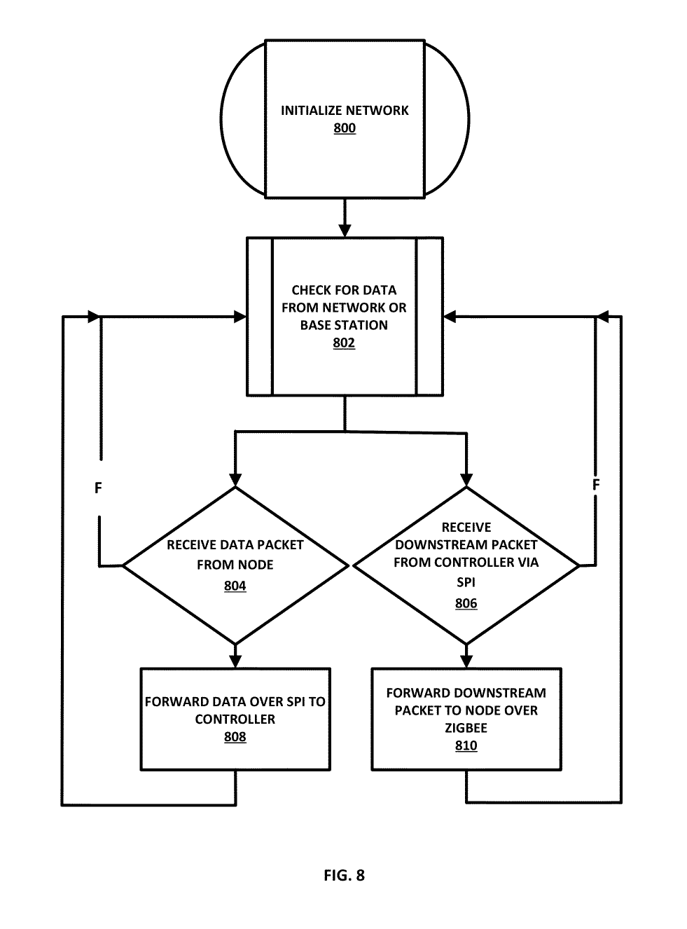

FIG. 8 illustrates a flow chart of high-level pseudo code of the ZigBee mesh network 702 shown in FIG. 7 in accordance with embodiments of the present disclosure. This example includes steps that may be implemented during hub initialization. Referring to FIG. 8, the method may start by initializing the network 702 (step 800). Subsequently, the method may check for data from the network or base station (step 802). At step 804, the method may check for any packets it should receive via node.js (from a remote server). Subsequently, data may be forwarded over serial peripheral interface (SPI) to the controller (step 808). At step 806, the method may check for any packets is should receive from load monitoring nodes (via SPI to the onboard ZigBee interface). Subsequently, the packet may be forwarded downstream to a node over ZigBee (step 810).

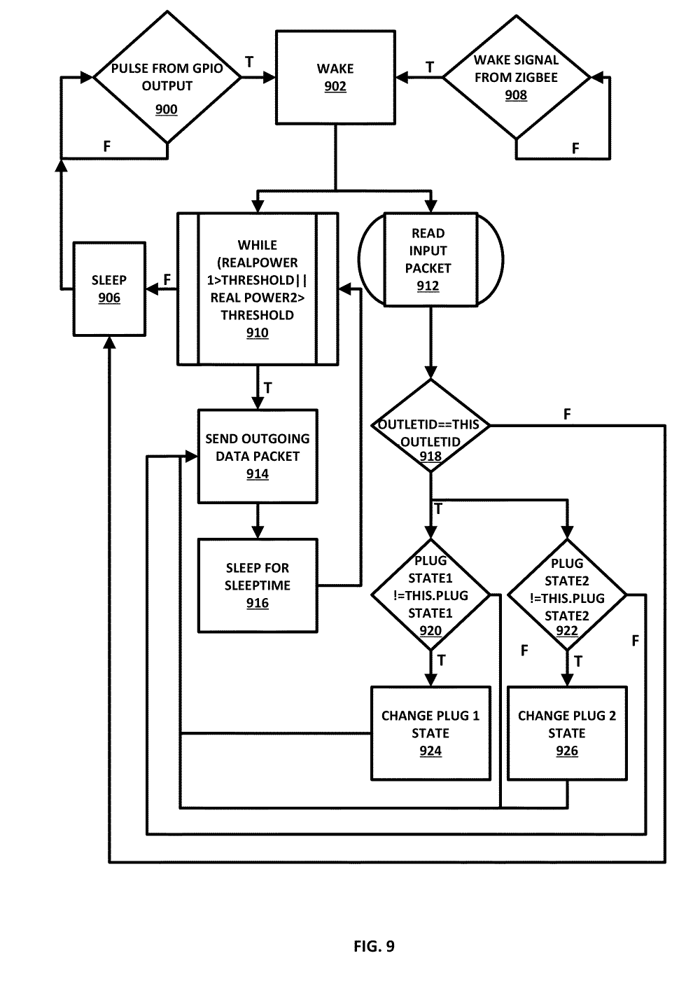

FIG. 9 illustrates a flow chart of high-level pseudo code of a microcontroller of an outlet or node 704 shown in FIG. 7 in accordance with embodiments of the present disclosure. Referring to FIG. 9, the method may include receiving a pulse from a GPIO output (step 900). In response to receipt of a pulse, the microcontroller may wake (step 902). The microcontroller may remain in the wake state while a signal is received from the ZigBee.

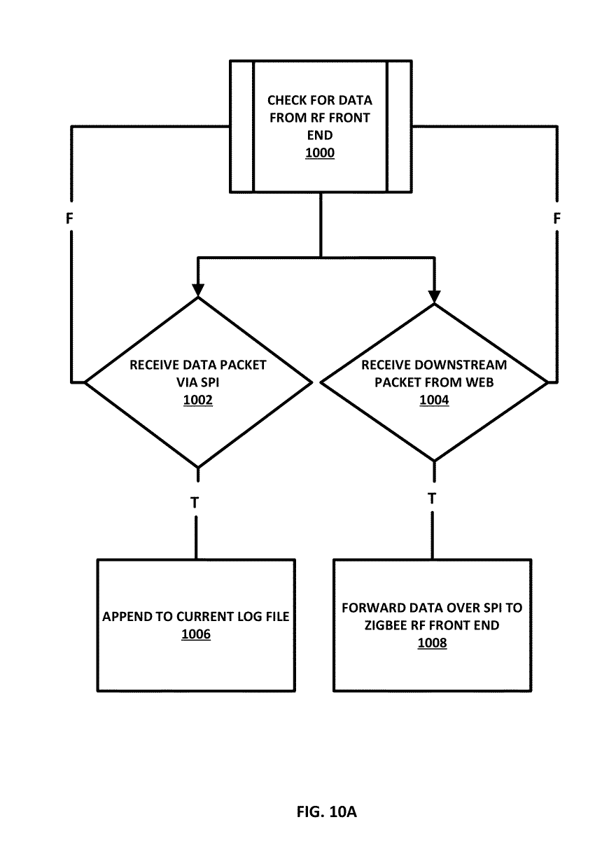

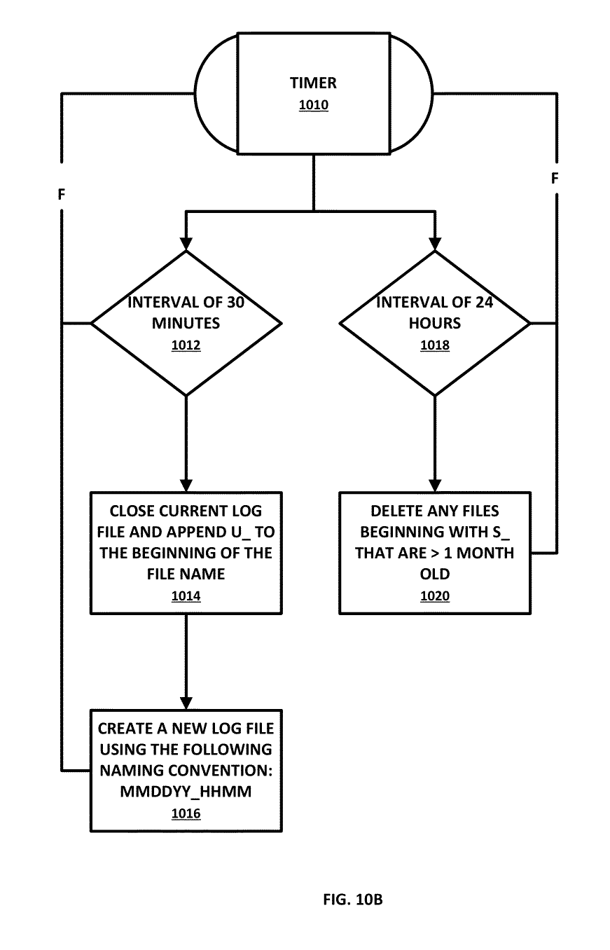

FIGS. 10A and 10B illustrate flow charts of high-level pseudo code of the controller 716 shown in FIG. 7 in accordance with embodiments of the present disclosure. Referring to FIG. 10A, the method may check for data from its RF front end 708 (1000). The data may have been received from one or more of the outlets 704.

Subsequently, the method of FIG. 10A may include receiving a data packet via SPI (step 1002) and receiving a downstream packet including control instructions from the web (step 1004). Subsequent to step 1002, the data within the data packet may be appended to a current database (step 1006). Subsequent to step 1004, the control instructions may be forwarded over SPI to a ZigBee RF front end 708 of an outlet 704. At step 1008, data may be sent to a load monitoring node via the ZigBee network interface. As an alternative to SPI, universal asynchronous receiver/transmitter (UART) protocol or any other suitable protocol may be utilized.

Referring to FIG. 10B, the method includes initializing a timer (step 1010). The timer may track intervals of 30 minutes (step 1012) at which a current log file is closed and data is appended to the beginning the beginning of the file (step 1014). The file name may be appropriately marked to indicate that it is closed. Subsequently, a new log file is created (step 1016). The new log file may be named in accordance with a naming convention indicating a current date and time. The new log file may be used for storing data.

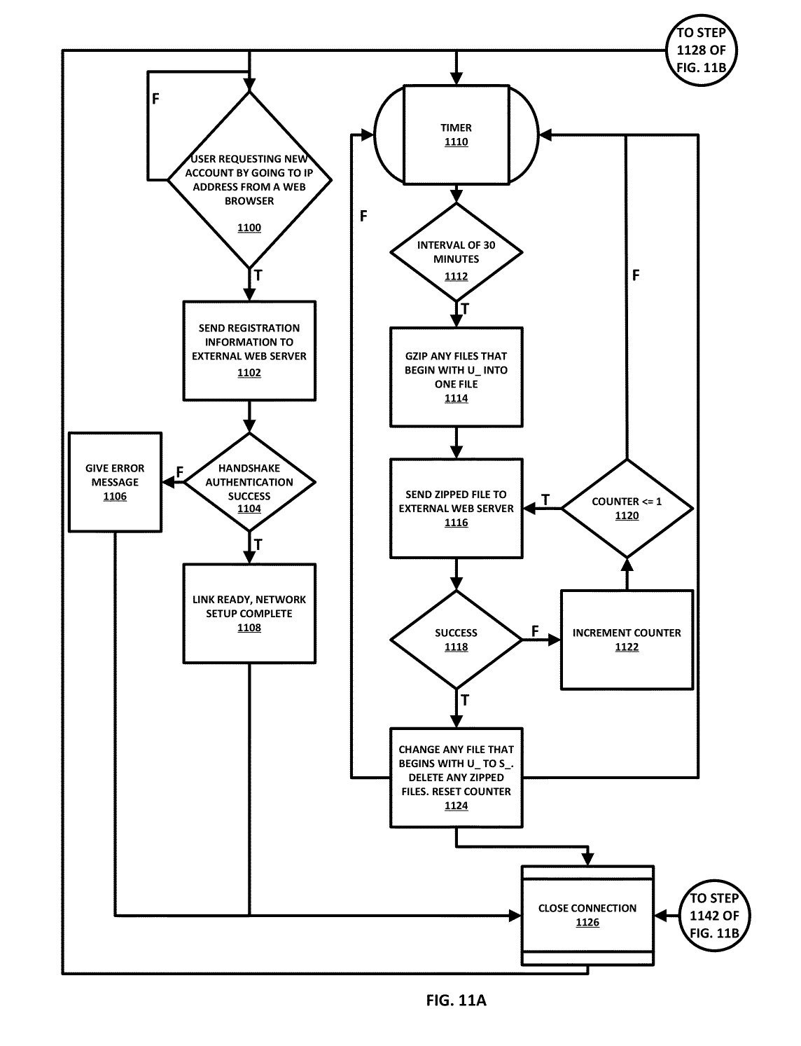

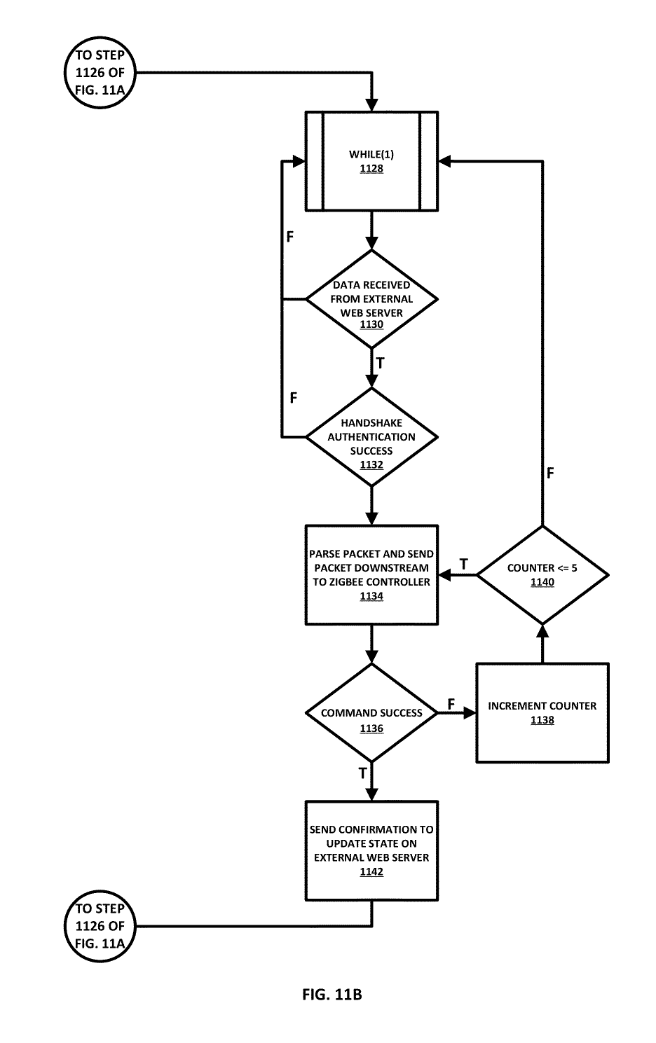

FIGS. 11A and 11B illustrate a flow chart of high-level pseudo code of the web server 714 as shown in FIG. 7 for communicating with a controller in accordance with embodiments of the present disclosure. Referring to FIGS. 11A and 11B, a user may request a new account by entering an IP address from a web browser at his or her computer (step 1100). The IP address may uniquely identify a website being managed by the web server 714 in accordance with the present disclosure. The user may enter registration information and send the registration information to the web server 714 (step 1102). Subsequently, the user's computing device and the web server 714 may handshake and conduct an authentication process (step 1104). If the authentication is unsuccessful, an error message may be given (step 1106). If the authentication is successful, a link may be established and network setup completed (step 1108).

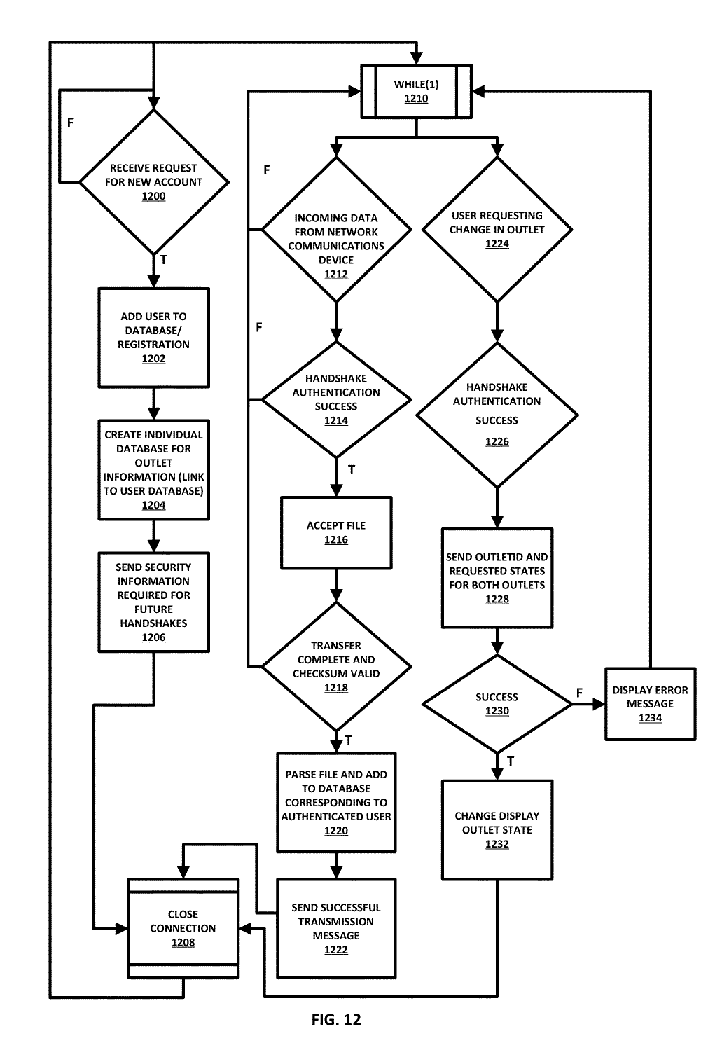

FIG. 12 illustrates a flow chart of high-level pseudo code of the web server 714 as shown in FIG. 7 in accordance with embodiments of the present disclosure. Referring to FIG. 12, the web server 714 may receive a request for a new account from a client computing device (step 1200). Subsequently, the web server 714 may add the user to a database and register the user (step 1202). The webs server 714 may create an individual database for outlet or node information (step 1204). The web server 714 may also send security information required for future handshakes (step 1206).

The web server 714 may also check for incoming data from the network communications device 104 (step 1212). In order to accept the data at step 1216, the web server 714 and the network communications device 104 can perform a security handshake (step 1214). After the file from step 1216 has been transferred, the checksum can be checked to make sure that it is valid (step 1218). If the data is valid, it may be parsed and added to the database corresponding to the authenticated user (step 1220). After the data is added to the database in step 1220, a confirmation message can be sent from the web server 714 to the network communications device 104 (step 1222).

The web server 714 may also accept a request from the user to change the state of an outlet (step 1224). In order to send the change request from step 1224, the web server 714 and the network communications device 104 can perform a security handshake (step 1226). After a successful authentication from step 1226, the web server 714 may send the change request to the network communications device 104 by including the outlet identifiers and the new requested states for both outlets (step 1228). The network communications device 104 can send the web server 714 a notification of success or failure (step 1230). If there was a failure, an error message is displayed to the user (step 1234). If the change was a success, the new outlet state is shown to the user (1232).

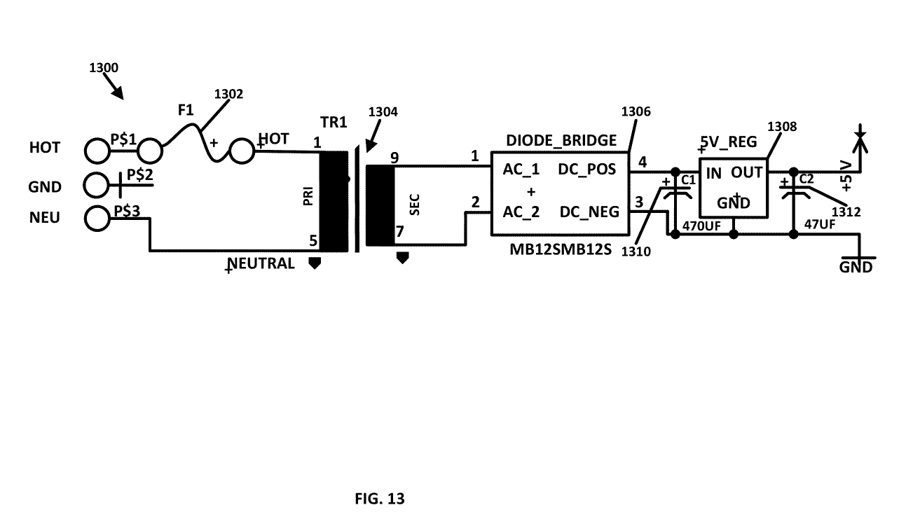

FIG. 13 illustrates a circuit diagram of a power supply 1300 in accordance with embodiments of the present disclosure. The power supply 1300 may be used for powering a load monitoring node. Referring to FIG. 13, the power supply 1300 is a transformer based power supply. In an alternative, the power supply may step down voltage from the line voltage being measured to the voltage of the components in the system. For example, the voltage may be stepped down to 3.3 V DC.

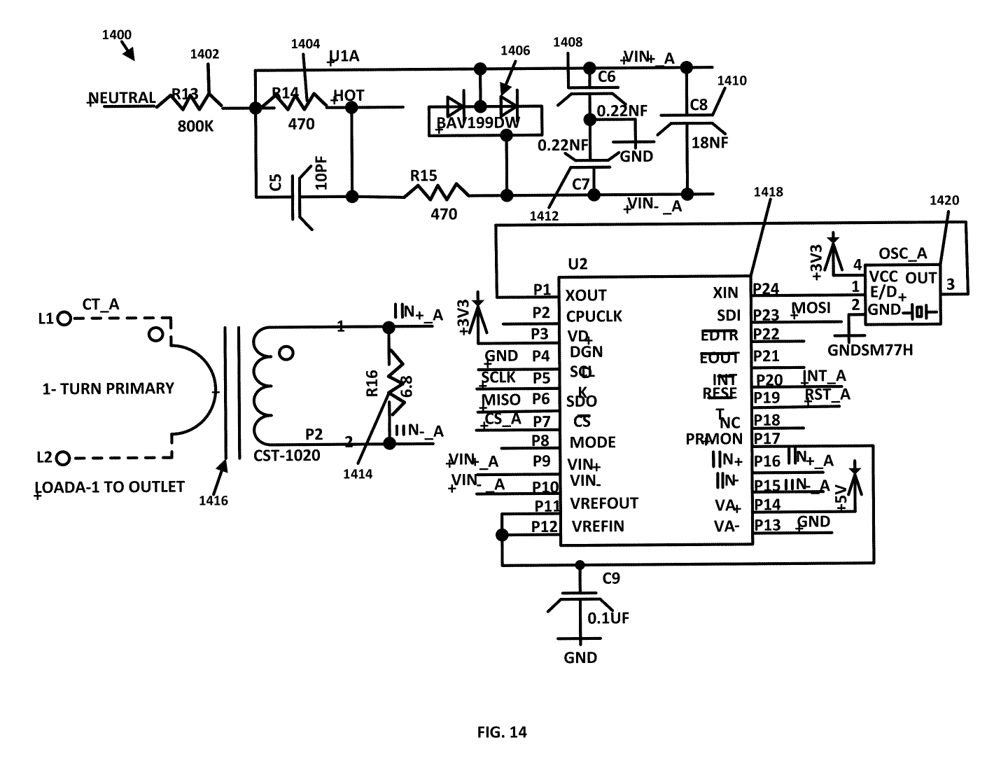

FIG. 14 illustrates a circuit diagram of a power measurement module 1400 in accordance with embodiments of the present disclosure. The module 1400 may be used for measuring power usage at a power measurement input. Referring to FIG. 14, the module 1400 may be part of, for example, the analog front end 210 shown in FIG. 2. Voltage may be proportionally reduced by voltage divider resistors 1602 and 1604 for input to, for example, the DSP 208 shown in FIG. 2. Diodes 1606 can be used on a voltage measurement circuit for surge protection. Other capacitors 1608, 1610, and 1612 are filtering capacitors that can reduce noise on voltage input. Current measurement can be measured by a current transformer 1616 and load resistor 1614. Voltage across load resistor 1614 is proportional to current measured. Chip 1618, in this example, is a type of DSP 208, Oscillator 1620 is used as clock on the DSP 208.

In accordance with embodiments, systems disclosed herein may be embedded and all nodes can learn to interact with each other. The nodes may be pulled together in a ZigBee or other suitable network. The network may be controlled by a ZigBee coordinator, which creates the network and controls data flow from nodes to a board, such as BeagleBoard, for processing. The network may be configured such that if a node loses power or drops off the network, the network can “heal itself” and still be functional. Most nodes send data upstream or execute an incoming command and subsequently goes to sleep. Some nodes may be configured as relay modules or routers that can bounce packets from other nodes upstream. Routers may be located in each room or area of a residence or commercial facility and may each act as a communications hub of that room or area. If a router drops off the network, an end device in that room or area may pick up that router's previous configuration.

Each device or component in a network, except the controller, may control its onboard load measuring modules. This may be implemented by an SPI interface and a command structure configured to obtain registers from the modules. Each plug in an outlet, for example, may have its own load measuring module such that the ZigBee device controls both plugs at the same time. The power data that the ZigBee device receives from the modules may be updated every second and stored in a data structure that keeps the data organized by each plug. The Vrms and Irms data registers may be read since average power is most easily obtained from multiplying these two values together.

In accordance with embodiments, load monitoring data and analysis information may be presented via a website. In an example, a website may have several different operational modules. Example modules include, but are not limited to, a configs module, a controllers module, a forms module, a layouts module, a models module, and a views module. The configs module may store basic site-wide information such as database passwords, file paths, page encodings, and error levels. Controllers module may control each webpage that is viewed by a user. The forms module may store forms as a separate element instantiated by a controller. In the layouts module, layouts may be used by every page on the site to give the pages formatting. In the models module, the model may be used to access tables in the database. The files in the models module may extend a database connector. In the views module, the module consists of dynamically generated, but mostly static, content that is generally available on every page. Some examples include the top bar and the side navigation bar. The scripts module may include HTML pages that are presented to the user. Each function in the controller may have a corresponding view script. Functions in the controller may pass information that is displayed by the script. The scripts may include both static HTML and dynamic PHP. The PHP may generate HTML output, such that all end users receive is the HTML.

A side bar on the left can be used to navigate the dashboard, system page, user profile page, or about page from any page in the site. The page may also provide power saving tips as well as a link to a government green power website. The top bar can be used to navigate the user profile page, or to logout from any page in the site.

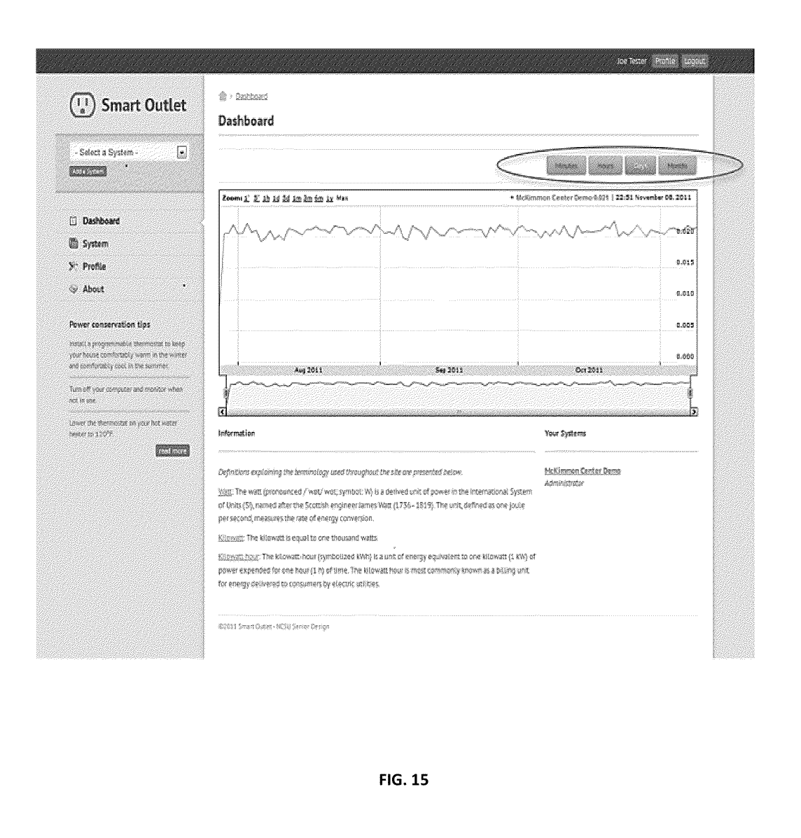

FIG. 15 depicts a webpage of an example user interface dashboard showing a day view in accordance with embodiments of the present disclosure. This time period is selectable by choosing a button located above the graph.

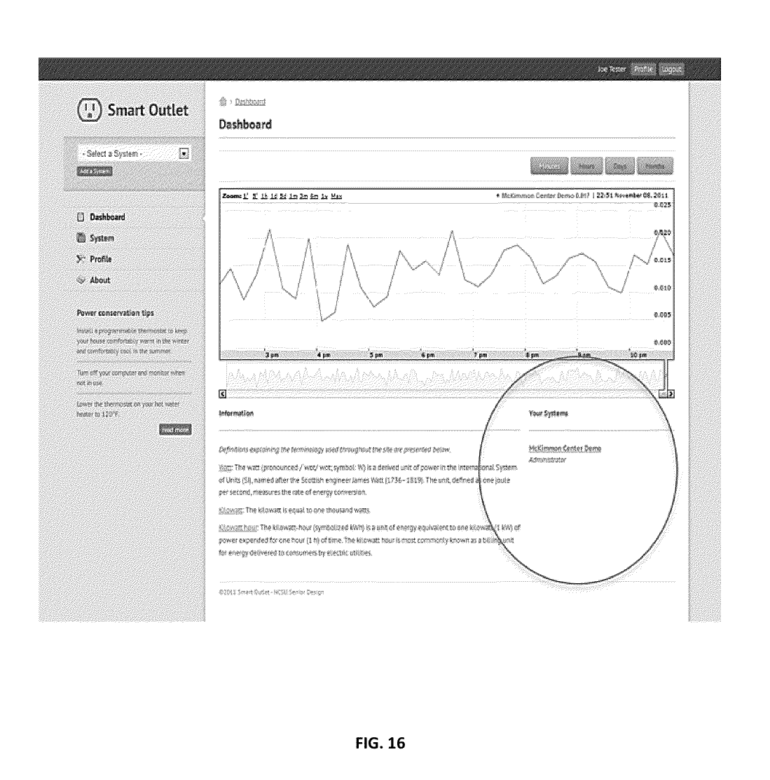

FIG. 16 depicts a webpage of an example user interface dashboard showing a minute view in accordance with embodiments of the present disclosure. This webpage also highlights (as indicated by the circle) that multiple facilities can be shown in the user interface dashboard.

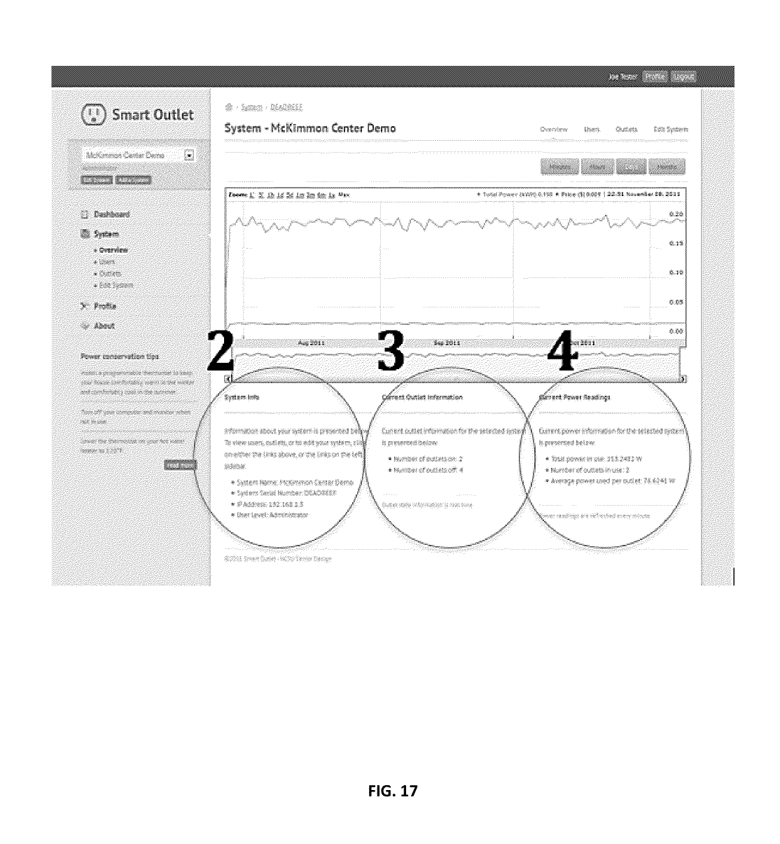

FIG. 17 depicts a webpage of an example user interface dashboard showing a system overview in accordance with embodiments of the present disclosure. Referring to FIG. 17, this webpage may be displayed in response to a particular system being selected by a user. The webpage may present a graph of total power used and cost along with control buttons for changing a time scale. In addition, the webpage may show system information including a system name, system serial number, system IP address, and user level. The webpage may also show current outlet information including, but not limited to, a number of outlets on and a number of outlets off. The webpage may also show current power readings including, but not limited to, a total power currently in use, a number of outlets currently in use, and an average power per outlet in use.

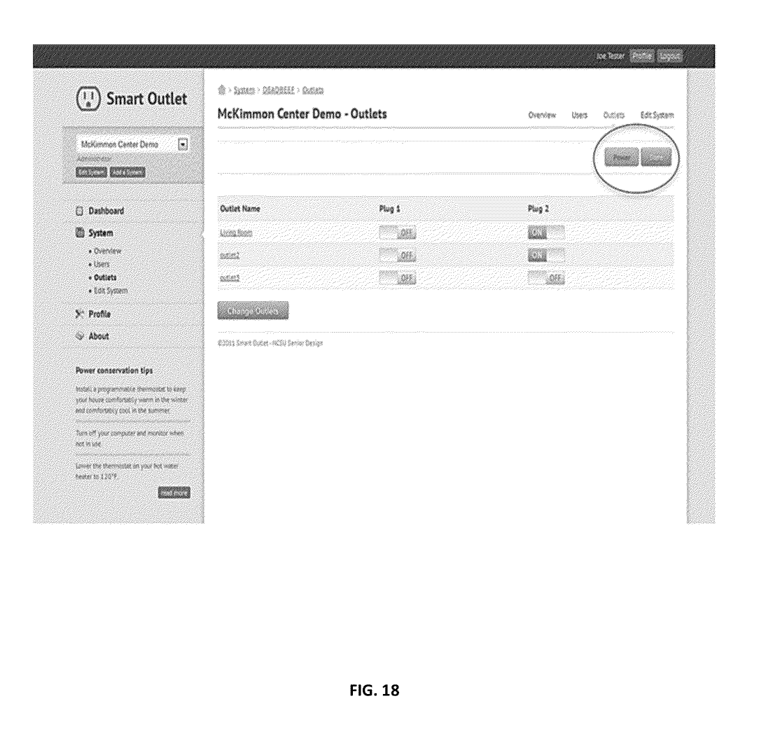

FIG. 18 depicts a webpage of an example user interface dashboard showing outlet overview states in accordance with embodiments of the present disclosure. Referring to FIG. 18, this webpage shows the state of each plug in that outlet. To change the states of plugs, the slider may be changed and the “Change Outlets” button selected. Power information may also be viewed for each plug.

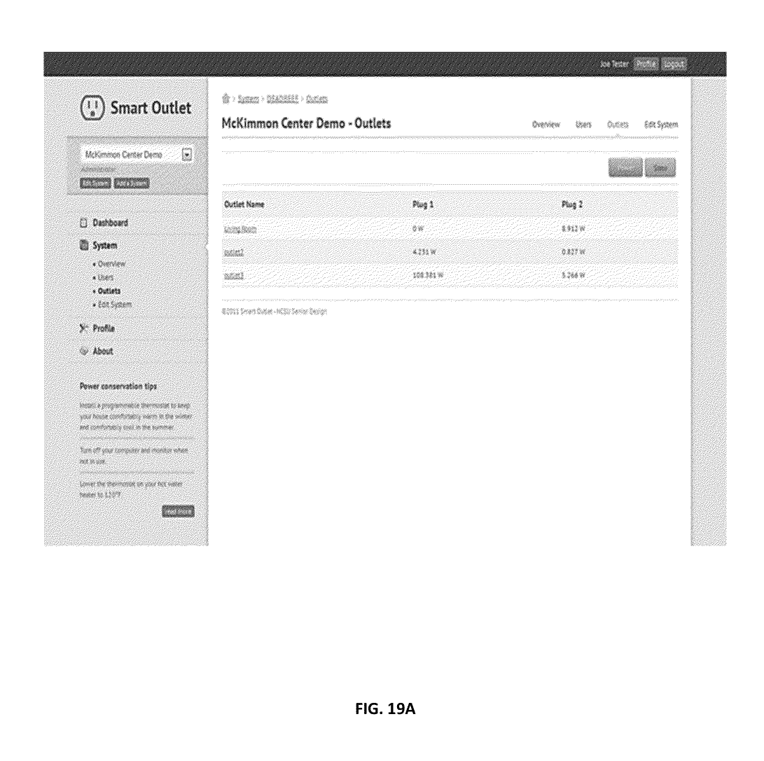

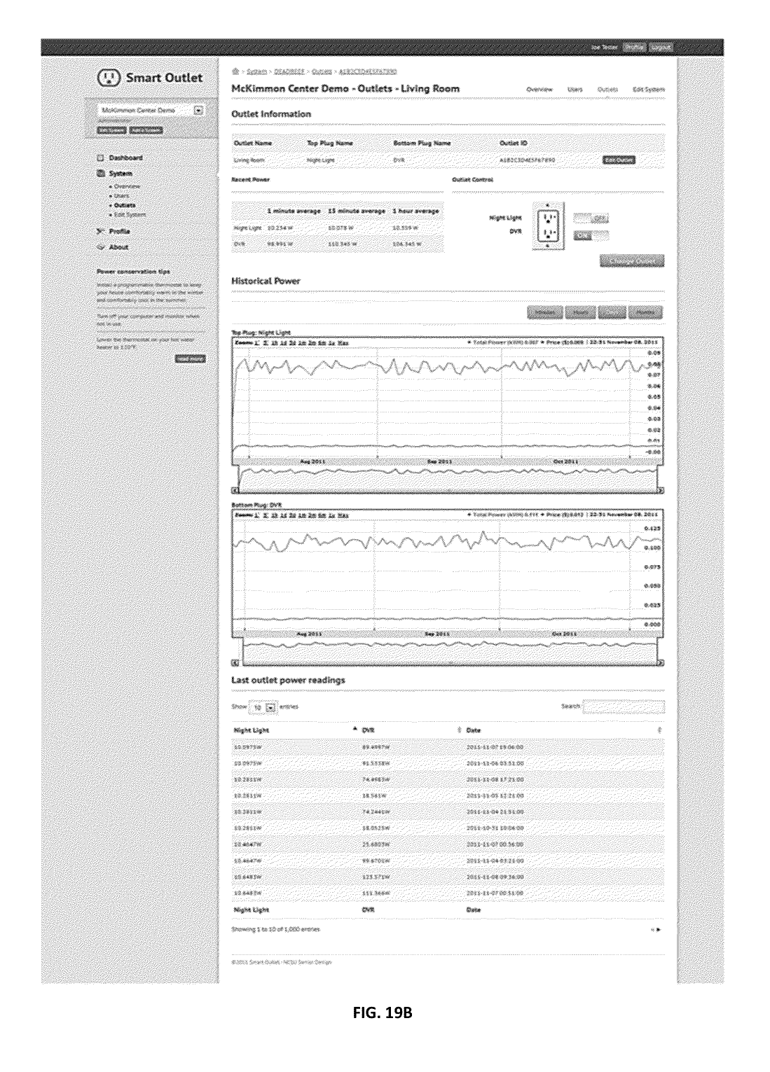

FIGS. 19A and 19B depict webpages of an example outlet overview in accordance with embodiments of the present disclosure. Referring to FIG. 19A, the webpage shows general information about the outlet, such as its name and identifier. An “Edit Outlet” button may be selected for allowing the user to edit a name of the outlet and its plugs. Below the outlet information is a chart for providing power reading averages for each plug from the last 1, 15, and 60 minutes. This state is represented both by an image of the LED and a switch. To change state, the switch may be changed and the “Change Outlet” button selected. Graphs are shown for the top and bottom plugs, respectively. Below the graphs is a table showing the 100 most recent power updates for the outlet. This table is sortable by any field by choosing the up or down arrow beside that field's title.

In accordance with embodiments, a load monitoring device may be installed behind a receptacle in an outlet box. As a result, the load monitoring device may be hidden from a user. The load monitoring device may monitor power usage or load data at the outlet in accordance with embodiments of the present disclosure. Further, the device may have power control capabilities as described herein.

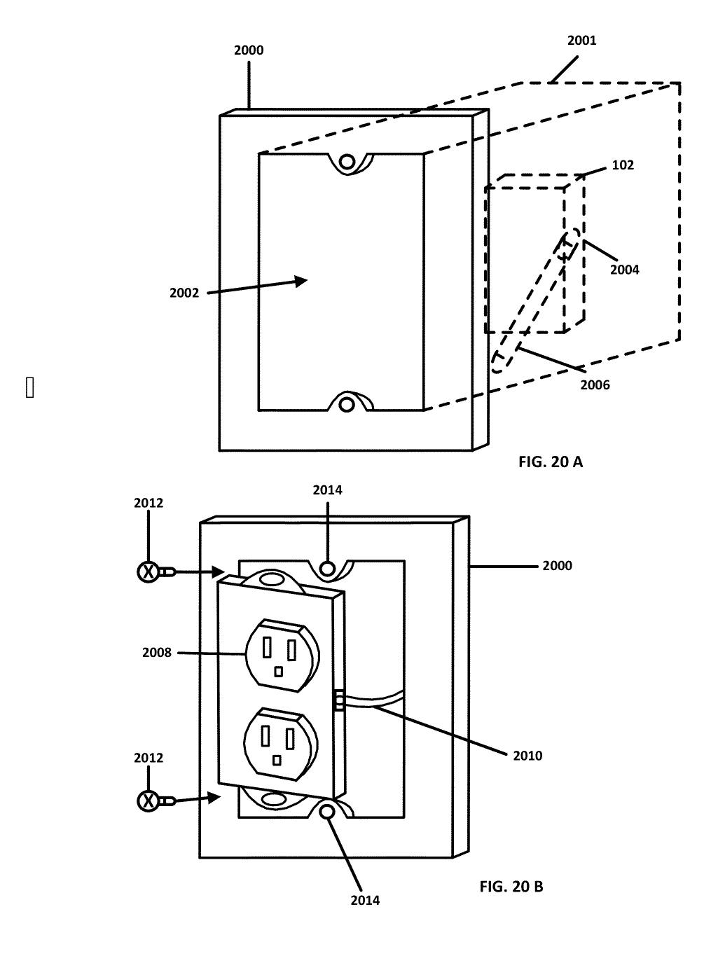

FIGS. 20A and 20B illustrate top perspective views of a load monitoring node 102 attached to an electrical outlet box 2000 in accordance with embodiments of the present disclosure. Referring to FIG. 20A, the node 102 may be suitably attached to a surface 2001 of an interior space 2002 defined by the box 2000. In this example, the node 102 includes an exterior frame 2004 within which hardware components of the node 102 may be held and protected from the outside environment. A suitable attachment mechanism (not shown) may attach the frame 2004 to the box 2000. For example, the attachment mechanism may include one or more surfaces on the frame 2004 to which adhesive may be applied for attachment to the surface 2001. Alternatively, the attachment mechanism may include one or more bolts for attaching the frame 2004 to the box 2000. The box 2000 may fit within a wall within a residence or commercial facility.

The node 102 may include one or more wires 2006 for electrically connecting to the wiring of the electrical outlet. In this way, the hardware components of the node 102 can electrically communicate with the wiring of the electrical outlet for capture of load data. Referring now to FIG. 20B, this view shows connection of an electrical plug box 2008 to the node 102 shown in FIG. 20A. One or more wires 2010 of the box 2008 may be attached to the wires 2006 of the node 102 in accordance with embodiments of the present disclosure. Further, the 2008 may include bolts 2012 for attachment of the box 2008 to the box 2000 at respective receiving holes 2014. A faceplate may then be positioned over and attached for covering the node 102, box 2000, and box 2008.

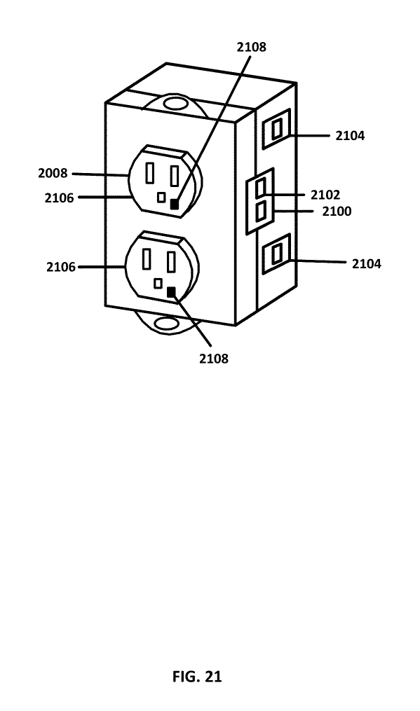

FIG. 21 illustrates a top perspective view of a load monitoring node 102 attached to an electrical plug receptacle 2008 in accordance with embodiments of the present disclosure. Referring to FIG. 21, in this example the node 102 may include an attachment mechanism for attaching directly to a backside of the receptacle 2008. For example, the node 102 may include a clip 2100 for attaching to a feature of the receptacle 2008. Alternatively, for example, the node 102 and receptacle 2008 may be screwed or bolted together. The receptacle 2008 and node 102 may be suitably fit within an electrical outlet box. The node 102 may include one or more terminals 2104 for electrical connection to wiring of the receptacle 2008. In this example, the wiring between the node 102 and receptacle 2008 may internal between the two components.

In accordance with embodiments, each plug 2106 may have an indicator 2108 integrated therewith for indication that the node 102 is active. As an example, the indicator 2108 may be a light emitter, such as, but not limited to, a light emitting diode (LED).

The various techniques described herein may be implemented with hardware or software or, where appropriate, with a combination of both. Thus, the methods and apparatus of the disclosed embodiments, or certain aspects or portions thereof, may take the form of program code (i.e., instructions) embodied in tangible media, such as floppy diskettes, CD-ROMs, hard drives, or any other machine-readable storage medium, wherein, when the program code is loaded into and executed by a machine, such as a computer, the machine becomes an apparatus for practicing the presently disclosed subject matter. In the case of program code execution on programmable computers, the computer will generally include a processor, a storage medium readable by the processor (including volatile and non-volatile memory and/or storage elements), at least one input device and at least one output device. One or more programs may be implemented in a high level procedural or object oriented programming language to communicate with a computer system. However, the program(s) can be implemented in assembly or machine language, if desired. In any case, the language may be a compiled or interpreted language, and combined with hardware implementations.

The described methods and apparatus may also be embodied in the form of program code that is transmitted over some transmission medium, such as over electrical wiring or cabling, through fiber optics, or via any other form of transmission, wherein, when the program code is received and loaded into and executed by a machine, such as an EPROM, a gate array, a programmable logic device (PLD), a client computer, a video recorder or the like, the machine becomes an apparatus for practicing the presently disclosed subject matter. When implemented on a general-purpose processor, the program code combines with the processor to provide a unique apparatus that operates to perform the processing of the presently disclosed subject matter.

Features from one embodiment or aspect may be combined with features from any other embodiment or aspect in any appropriate combination. For example, any individual or collective features of method aspects or embodiments may be applied to apparatus, system, product, or component aspects of embodiments and vice versa.

While the embodiments have been described in connection with the various embodiments of the various figures, it is to be understood that other similar embodiments may be used or modifications and additions may be made to the described embodiment for performing the same function without deviating therefrom. Therefore, the disclosed embodiments should not be limited to any single embodiment, but rather should be construed in breadth and scope in accordance with the appended claims.

What is claimed:

1. A load monitoring system comprising:
a plurality of load monitoring nodes each being in communication with a power measurement input and each being configured to capture load data at the respective power measurement input; and
a network communications device configured to receive the captured load data from each of the load monitoring nodes and to communicate the captured load data to a remote computing device.

2. The load monitoring system of claim 1, wherein the plurality of load monitoring nodes includes first and second load monitoring nodes, and
wherein the first load monitoring node communicates its respective captured load data to the second load monitoring node, and
wherein the second load monitoring node includes a relay function configured to communicate the captured load data of the first load monitoring node to the network communications device.

3. The load monitoring system of claim 1, wherein each of the load monitoring nodes is configured to communicate the captured load data to the network communications device.

4. The load monitoring system of claim 1, wherein each of the load monitoring nodes is configured to periodically communicate the captured load data to the network communication device.

5. The load monitoring system of claim 1, further comprising a wireless local area network (WLAN) including the load monitoring nodes, and
wherein the network communications device is configured with gateway functions for managing communications between the WLAN and the Internet, the network communications device being configured to communicate with the remote computing device via the Internet.

6. The load monitoring system of claim 1, wherein the remote computing device is configured to:
process the captured load data to generate analysis information; and
present the analysis information to a user.

7. The load monitoring system of claim 6, wherein the remote computing device is configured to communicate with a client computing device for presenting the analysis information to the user at the client computing device.

8. The load monitoring system of claim 1, wherein each of the load monitoring nodes is configured to control power output at its respective power measurement input.

9. The load monitoring system of claim 8, wherein each of the load monitoring nodes is configured to receive instructions for controlling the power output at its respective power measurement input.

10. The load monitoring system of claim 1, wherein at least one of the load monitoring nodes includes a battery for powering the at least one load monitoring node, wherein the load is determined based on a non-contact inductive current measurement.

11. The load monitoring system of claim 1, wherein at least one of the load monitoring nodes is configured to receive power from its respective power measurement input, wherein the load is determined based on a direct line connection for measuring voltage and an inductive current measurement.

12. The load monitoring system of claim 1, wherein at least one of the load monitoring nodes comprises a battery and is operable in a battery-powered mode during which the battery is charged via an inductive coupling to a power line.

13. The load monitoring system of claim 1, wherein at least one of the load monitoring nodes is configured to operate in first and second power modes that are user selectable,
wherein, in the first power mode, the at least one of the load monitoring nodes receives power from a battery, and
wherein, in the second power mode, the at least one of the load monitoring nodes receives power from its respective power measurement input.

14. A method of load monitoring, the method comprising:
at each of a plurality of load monitoring nodes that are each in communication with a power measurement input, capturing load data at a respective power measurement input; and
at a network communications device:
receiving the captured load data from each of the load monitoring nodes; and
communicating the captured load data to a remote computing device.

15. The method of claim 14, further comprising:
at a first load monitoring node among the plurality of load monitoring nodes, communicating its respective captured load data to a second load monitoring node among the plurality of load monitoring nodes; and
at the second load monitoring node, communicating the captured load data of the first load monitoring node to the network communications device.

16. The method of claim 14, further comprising:
configuring the load monitoring nodes in a wireless local area network (WLAN); and
at the network communications device:
managing communications between the WLAN and the Internet; and
communicating with the remote computing device via the Internet.

17. The method of claim 14, at the remote computing device:
processing the captured load data to generate analysis information; and
presenting the analysis information to a user.

18. The method of claim 17, at the remote computing device, communicating with a client computing device for presenting the analysis information to the user at the client computing device.

19. The method of claim 14, at each of the load monitoring nodes, controlling power output at its respective power measurement input.

20. The method of claim 19, wherein each of the load monitoring nodes is configured to receive instructions for controlling the power output at its respective power measurement input.

21. The method of claim 14, further comprising operating at least one of the load monitoring nodes either a first power mode or a second power mode,
wherein, in the first power mode, the at least one of the load monitoring nodes receives power from a battery, and
wherein, in the second power mode, the at least one of the load monitoring nodes receives power from its respective power measurement input.
